(19) United States
(12) Patent Application Publication
(10) Pub. No.: US 2016/0133461 A1
(43) Pub. Date: May 12, 2016

(54) METHOD TO GROW A SEMI-CONDUCTING SIC LAYER

(71) Applicants: Erik JANZÉN, Linköping (SE); Olof KORDINA, Vikingstad (SE)

(72) Inventors: Erik Janzén, Linköping (SE); Olof Kordina, Vikingstad (SE); Urban Forsberg, Sturefors (SE)

(21) Appl. No.: 14/902,170

(22) PCT Filed: Jun. 27, 2014
(86) PCT No.: PCT/SE2014/050807

§ 371 Date: Dec. 30, 2015

(30) Foreign Application Priority Data
Jul. 1, 2013 (SE) 1330085-0
Feb. 19, 2014 (SE) 1430022-2

(51) Int. Cl. H01L 21/02; H01L 29/66; H01L 21/304

(52) U.S. Cl. CPC H01L 21/02447; H01L 21/02381; H01L 21/0254; H01L 21/304; H01L 29/66462

(57) ABSTRACT

A method to grow a semi insulating SiC layer. The method may include growing the semi insulating SiC layer on a substrate, and creating deep defects in the grown semi insulating SiC layer, whereby a semi insulating property is created in the grown semi insulating SiC layer. Alternatively, the method may include growing a semi insulating SiC layer, creating deep defects in the grown semi insulating SiC layer, whereby the semi insulating property is created in the grown semi insulating SiC layer, and using source material during the growth such that the semi insulating SiC layer is made isotope enriched.

### TECHNICAL FIELD

The present invention is directed to growth of a Semi Insulating (SI) layer on a wafer. In particular, the invention deals with forming Silicon Carbon (SiC) substrates having Semi Insulating properties.

### BACKGROUND

High purity wafers require, as the name says, that the background impurities are at a low level. Normally background impurities should be below 10¹⁶ cm⁻³. When the SiC crystals are grown using physical vapor transport (PVT, also known as seeded sublimation growth) or HTCVD (High Temperature Chemical Vapour Deposition), several intrinsic defects are formed at a level around 10¹⁶ cm⁻³ or just below. These defects can be vacancies, divacancies, anticites, etc. Some of these defects are easily annealed out but in particular the carbon vacancy is interesting for SI wafers as said carbon vacancy defect is deep and very stable. Typically, high purity SI wafers have resistivities above 10⁹ Ωcm, usually much higher. The background doping of the impurities must be below the level of carbon vacancies in order to make the method work. This makes it hard to produce such crystals as impurities are difficult to get rid of using PVT. The stoichiometry is also very silicon rich at the start of the crystal growth which promotes n-type doping and it gradually changes to become more carbon-rich at the end of the growth cycle which promotes p-type doping. It is thus not unusual to have crystals with n-type behavior in one end, SI behavior in the center, and p-type behavior at the far end closest to the crown of the crystal.

Vanadium doped crystals are no easier to produce, though the background doping levels may be higher. However, the vanadium doping, which similar to the carbon vacancy produces a deep level (recombination center) in the material, must be higher than the background impurity level. Vanadium doping may not be too high as the impurity may build in stress in the material which can create other types of unwanted defects such as dislocations. The background doping of the impurities must therefore be kept at a reasonably low level. SI wafers are mainly used to grow group III-N high electron mobility (HEMT) structures on them. The group III elements are usually Al, Ga, and In and most commonly today is the use of AlGaN/GaN HEMT structures. These structures are then processed into HEMT devices, but before dicing the wafer into separate components, the wafer is thinned down to 50-100 μm thickness. This is done to improve the heat dissipation from the device. The lower the channel temperature is kept during operation, the better the efficiency of the device and the longer the lifetime of the device: The heat produced in the channel can easily form dislocations that reduce the efficiency and eventually destroy the device.

The semi insulating (SI) substrates of SiC are today very expensive. Usually a factor of three to four more expensive than the nitrogen doped conducting substrates. Partly this can be explained by the much larger produced and sold volume of conducting substrates as compared to SI substrates. But it is more difficult to manufacture SI substrates and yields are normally quite low. The two types of SI wafers that are produced are the high purity wafers and the vanadium doped SI wafers

### DESCRIPTION OF THE INVENTION

One first aspect of the invention is to take a low cost n-type wafer, for instance a nitrogen doped on-axis 4H SiC wafer or an n+ nitrogen doped 4 degrees off axis 4H SiC wafer, or a nitrogen doped 6H-SiC wafer and grow an SI epitaxial layer that is 100-150 μm thick, using e.g. chemical vapor deposition, CVD. The SI properties can be realized using vanadium doping or by choosing growth conditions that create intrinsic defects at a higher concentration than the shallow defects in the layer. Intrinsic defects are usually only manifest in concentrations high enough to make the material SI if the growth temperature is above 2000° C. When the growth temperature is lower, the concentration of the intrinsic defects is usually lower than the concentration of the shallow impurities, such as nitrogen, and the resulting material will hence be of n-type. Also the C/Si ratio can be varied to make the material SI. When the C/Si ratio is increased i.e. more carbon is introduced compared with Si, the nitrogen doping is reduced which hence can lower the background doping of shallow defects to below that of the intrinsic deep defects e.g. the carbon vacancy.

After the growth of the SI layer, the surface should be polished and prepared for the GaN/AlGaN epitaxial growth. At the end of the processing, the original wafer will anyway be polished away leaving only the epitaxial SI pseudo-wafer with HEMT devices grown on the grown SI layer on top. To our knowledge this has not been done.

A second aspect of the invention which can be combined with the first aspect is to make the SI SiC epitaxial layer isotope enriched which would enhance the thermal conductivity and improve the performance of the finished devices.

A third aspect of the invention is that an SI isotope enriched SiC substrate can be produced and a GaN/AlGaN HEMT device can be grown and processed in the normal way they are produced today. This would not be commercially favorable as the isotope enriched substrate will be substantially more expensive to produce but it nevertheless has some advantages: After growing the GaN/AlGaN structure on the SiC substrates the sheet resistance can easily be measured which is more complicated (though it is possible) if an n+ substrate is used with an SI isotope enriched SiC layer on top as described above.

Still another aspect, a fourth aspect of the invention is to create a thick SI layer on a regular Si substrate. This layer will be 3C-SiC and it can be made isotope enriched of course. Before growing a GaN/AlGaN HEMT structure on the thick SI layer, the surface will need to be polished. After processing, the Si wafer will be polished away similar to what is described previously where the n+ SiC substrate is polished away. The Si wafer will be much easier to polish (or etched away). The SiC layer that is grown on Si wafers is normally very dislocated the first 5-10 μm, and it is good if this 5-10 μm part of the grown SI SiC layer is polished away as well.

### Epitaxial Semi Insulating Sic Substrates Produced by CVD on Low Cost N+ Substrates.

The cost of producing a high purity SI SiC substrate using Physical Vapor Transport (PVT) is substantially higher than producing an n+ SiC substrate. The purity of the source material and ingoing graphite components must be controlled and kept very low. The SI properties come from intrinsic defects such as carbon vacancies that are present at a low concentration in the material grown at these high temperatures. Once the concentration of point defects such as boron, aluminum, and nitrogen becomes low enough the intrinsic defects dominate and make the material Semi Insulating. N+SiC substrates do not require such a rigorous purification of the source material prior to the growth. The volume is furthermore much higher which brings the price of the n+ SiC substrates down substantially.

When a GaN HEMT device is produced, an SI high purity or vanadium doped substrate is used. The vanadium also makes the material SI. Once the device is finished, the substrate is generally thinned down to between 50-100 μm. Our idea is to make an SI epitaxial layer of about 100 μm thick on a regular low cost n+ SiC substrate. Then the GaN HEMT device is made and when the substrate is thinned down it is the n+ substrate that is removed leaving only the SI epitaxial layer behind with the GaN device on top. Of course, the SI epitaxial layer can be made isotope enriched which would make it better performing as well compared to a regular SI substrate.

### GaN/AlGaN HEMT Devices on Si Isotope Enriched Sic Substrates.

Should the difficulties in measuring sheet resistance prove to be too large, a complete isotope enriched SI SiC substrate may be produced (as the third aspect mentioned). This can be done using various growth techniques e.g. PVT, HTCVD, or CVD. The seed crystal can be made of natural SiC but the precursors that are used should/must be isotope enriched. Especially the silicon precursors must be isotope enriched as this has the greatest influence on the thermal conductivity. The carbon precursor need not be isotope enriched as it will only improve the thermal conductivity by an additional two to three percent according to calculations. If the crystal is thick enough after the growth it can be sliced into thick substrates that may be lapped and polished in a regular manner to produce a nice isotope enriched substrate ready for GaN/AlGaN epitaxial growth. In case the crystal is thinner, it can directly be lapped and polished without slicing. It is important to lap off the original substrate completely if this is natural SiC.

The remaining procedure follows the standard procedure i.e. a GaN/AlGaN HEMT structure is grown and, since the whole substrate is SI, characterized with respect to sheet resistance, and finally processed into devices. Finally, after processing but before dicing, the substrate is thinned down to about 50-100 μm.

As can be concluded from the description, producing a HEMT device on an SI isotope enriched substrate would be a substantially more expensive way of producing the HEMT than growing a 100 μm thick layer on top of an n+ substrate. It would also waste a lot of isotope enriched material. The only advantage in using a whole isotope enriched SI SiC substrate would be the fact that routine characterization methods established in the production can be used.

If the characterization is considered essential, a natural SI SiC substrate can be used prior to growing an isotope enriched SI layer on top of it. This would make it more expensive on the other hand. Alternatively, a natural SI epitaxial layer can be grown on an n+ SiC substrate followed by an isotope enriched SI SiC layer. The n+ layer can subsequently be lapped off prior to the growth of the GaN/AlGaN epitaxial growth. This would enable routine characterization to be used but the structure will be somewhat more expensive than just growing an isotope enriched SI layer directly on top of a n+ SiC substrate.

A way to achieve isotope enriched material is to use isotope enriched source material (in the form of powder or chunks) when growing the SiC material. In the PVT growth method, the isotope enriched powder is used directly as the source material in the reactor. In the HTCVD growth method, the powder is produced in-situ in the reactor through the reaction of the isotope enriched precursor gases e.g. silane and methane or ethylene. The powder or the precursor gases need only be enriched on the Si-side which would give crystals with slightly more than 20% improvement in thermal conductivity as compared to natural SiC. With the statement “enriched only on the Si-side is meant that only the Si atoms contained in the source material (powder, chunks, precursor gases) need to be isotope enriched. Of course, a few percent gain of the thermal conductivity may be obtained if the powder is enriched also on the carbon side (the C atoms contained in the source material), but the question is whether this is economically defensible.

In PVT growth, the powder is usually synthesized using silicon powder and graphite powder in a hot ambient. The produced material is usually crushed to form SiC chunks or particles. To make isotope enriched SiC, one would typically use the ²⁸Si isotope which has the highest natural abundance and is therefore the one that is easiest to separate at high purity and lowest cost. Likewise the ¹²C isotope is used on the carbon side (¹²C has 98.9% natural abundance). ¹²C is fairly readily available as a byproduct of ¹³C production for medical use. In HTCVD growth, the powder is, as mentioned, produced in situ through the reaction of source gases which usually are silane and ethylene. Methane can be used here also with a slight modification of the growth parameters. To produce isotope enriched crystals or thick epitaxial layers using HTCVD one would again use ²⁸SiH₄ and ¹²CH₄ as precursors. As mentioned, using an isotope enriched carbon source is not necessary in order to obtain sufficiently good thermal conductivity improvement. It is most important to enrich on the Si side. Isotope enriched ²⁸Si with a purity of 99% (92.23% in natural abundance) would give a thermal conductivity improvement of around 20% with no enrichment on the carbon side according to calculations. It is not too difficult to enrich up to 99% and it is common with higher enrichment (better than 99.9%). The extra enrichment on the Si side from 99% to 99.9% would improve the thermal conductivity perhaps an additional percent. Enriching on the carbon side would add additionally 2-4% to the thermal conductivity.

### LIST OF FIGURES

FIGS. 1a and 1b schematically show a cross section of a wafer in a description of a method to manufacture a HEMT structure by use of a low cost conventional n⁺ SiC substrate.

FIGS. 2a and 2b schematically show a cross section of a wafer in a description of a method to manufacture a HEMT structure by use of a Semi Insulating SiC substrate.

FIGS. 3a and 3b schematically show a cross section of a wafer in a description of a method to manufacture a HEMT structure by use of a low cost conventional Si substrate.

### DESCRIPTION OF EMBODIMENTS OF THE INVENTION

The processes for realizing an SI epitaxial SiC layer upon which HEMT structures can be arranged as discussed above are described herein with reference to the drawings.

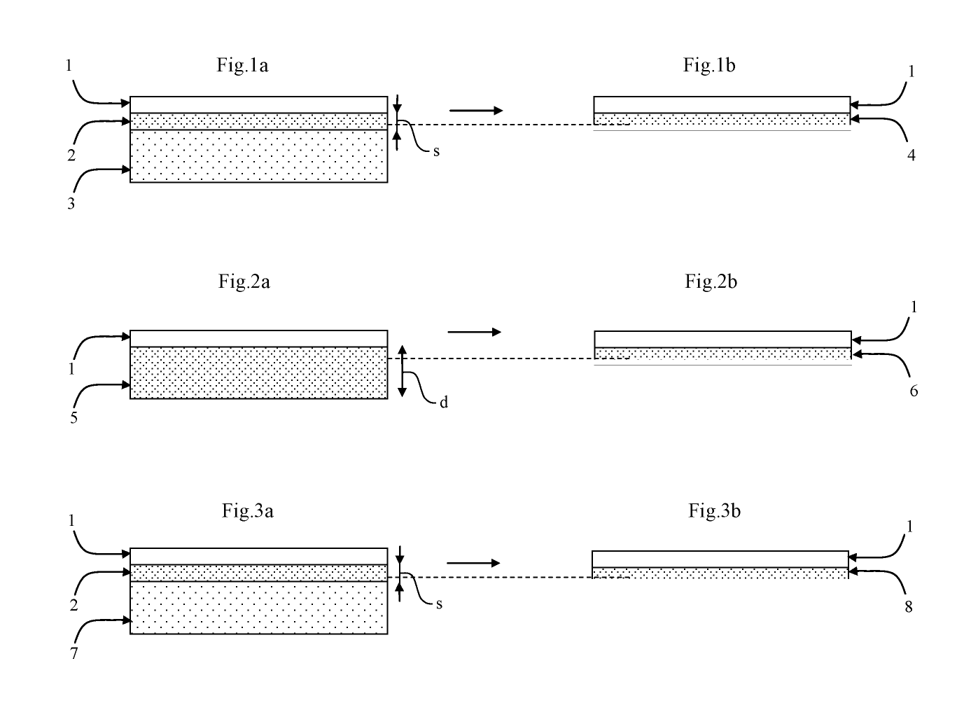

According to the first aspect of the invention (see FIGS. 1a and 1b) an n⁺ SiC base-substrate 3 is used for growth of an epitaxial Semi Insulating SiC layer 2 upon the n⁺ SiC base-substrate. The SI epitaxial layer 2 can be grown to a thickness s between 30 μm and 350 μm. A GaN/AlGaN HEMT structure 1 on a wafer consisting of layers 2+3 can be formed by conventional technique. The n⁺ SiC base-substrate is a low cost material compared to the conventionally used Semi Insulating SiC substrates as a base for the growth of a HEMT structure. In combination, the n⁺ SiC base-substrate 3 and the grown SiC epitaxial layer 2 can now be utilized as the wafer for growth of the HEMT structure 1 on the SI surface of the wafer 2+3. After polishing the surface and after application of the HEMT structure 1, the whole base-substrate 3, and optionally a thin layer of the grown SI SiC layer 2 is polished or etched away to form the pseudo-wafer 4 as shown in FIG. 1b. As stated, the wafer 2+3 is, after the HEMT structure 1 is applied, thinned down to a pseudo-wafer 50 μm to 150 μm or preferably 50 μm to 100 μm in thickness.

To improve the quality of the wafer 2+3, the SI SiC epitaxial layer 2 can, according the second aspect of the invention, be made isotope enriched The way to achieve this is discussed above for growth of such an isotope enriched SI SiC layer on top of the base-substrate 3 in a PVT reactor as well as in an HTCVD reactor. Otherwise, the characterization of the corresponding features are the same as in aspect one of the invention.

According to the third aspect of the invention (See FIGS. 2a and 2b), a conventional Semi Insulating Silicon Carbide substrate is used as the base substrate 5. But, in contrast to prior art technology the base substrate 5 in this embodiment is isotope enriched. The processes for arriving at isotope enriched SiC material is described above for PVT and HTCVD reactors. On the base-substrate 5 is then a GaN/AlGaN epitaxial layer 1 grown. The base-substrate 5 serves, in this aspect of the invention, as a single layer wafer for growing the GaN/AlGaN epitaxial HEMT structure layer 1. After the addition of said GaN/AlGaN epitaxial layer 1 the main part of the original base-substrate 5 is polished or etched away at a region offset from the on-grown epitaxial layer 1. The base substrate 5 used in this embodiment may suitably have a thickness d around 350 μm. After the application of the HEMT structure 1, the start wafer, in this case the single base substrate 5, is thinned down to a pseudo-wafer 6 with a thickness within the interval 50<d<150 μm, or preferably within the interval 50<d<100. See FIG. 2b.

According to the fourth aspect of the invention a low cost regular Si (Silicon) substrate is used as base substrate 7. An SI SiC epitaxial layer 2 is grown on the surface of base-substrate 7. The layer 2 grown will be a 3C-SiC polytype layer. A layer 1, as previously a GaN/AlGaN HEMT structure, is then grown on the polished wafer 2+7 consisting of the Si-base substrate 7 and the on-grown SI SiC layer 2. Before application of the GaN/AlGaN HEMT structure 1, the surface of wafer 2+7 should be polished. As previously, part of the wafer 2+7 will be removed. This is achieved by polishing or etching away the Si base substrate 7 and preferably also a thin film of the applied SiC material 2 amounting to a thickness of, for example, 5 μm to 10 μm closest to the removed Si layer. The remaining part of the Semi Insulating SiC epitaxial layer 2 then forms a pseudo-wafer 8 as shown in FIG. 3b. The thickness s of the layer 2 may also in this embodiment be in the same range as in the first aspect of the invention.

In the embodiments discussed above the growth of the epitaxial layer on any of the base substrates 3, 5, 7 is preferably made as on-axis growth.

Characterizing growth data according to the invention:

The thickness of the grown SI SiC layer is in the range of 30 μm to 350 μm. When an SI epitaxial layer is formed the thickness is preferably in the range of 50 μm-200 μm, or most preferably in the range of 50 μm-150 μm. When natural SiC is grown to form the SI SiC layer with isotope enriched properties, the thickness of the layer can be up to 350 μm.

The growth conditions for growing the SI layer are chosen such that deep intrinsic defects dominate over shallow point defects achieved by one of the steps:
growing the layer in a temperature between 1600° C. to 2200° C.,
or preferably growing the layer in a temperature between 1650° C. to 2000° C.,
or most preferably growing the layer in a temperature between 1650° C. to 1900° C.

The growth conditions for growing the SI layer are chosen such that deep intrinsic defects dominate over shallow point defects achieved by one of the steps:
during the growth the C/Si ratio is kept between 0.9-3,
or preferably during the growth the C/Si ratio is kept between 0.9-1.5.

1. A method to grow a semi insulating SiC layer, the method comprising:
A) growing the semi insulating SiC layer on a substrate, and
creating deep defects in the grown semi insulating SiC layer, whereby a semi insulating property is created in the grown semi insulating SiC layer, or
B) growing a semi insulating SiC layer,
creating deep defects in the grown semi insulating SiC layer, whereby the semi insulating property is created in the grown semi insulating SiC layer, and
using source material during the growth such that the semi insulating SiC layer is made isotope enriched.

2. The method according to claim 1, where said deep defect is created by one of:
vanadium doping,
intrinsic defects formed during the growth, and
a combination of vanadium doping and intrinsic defects.

3. The method according to claim 1, wherein according to A) the grown semi insulating SiC layer has a thickness in a range of 30 μm to 200 μm, and wherein according to B) the grown semi insulating SiC layer has a thickness between 50 μm and 350 μm.

4. The method according to claim 1, wherein growth conditions of the semi insulating SiC layer are chosen such that deep intrinsic defects dominate over shallow point defects which is achieved by one of:
growing the semi insulating SiC layer in a temperature between 1600° C. to 2200° C.,
growing the semi insulating SiC layer in a temperature between 1650° C. to 2000° C., or
growing the semi insulating SiC layer in a temperature between 1650° C. to 1900° C.

5. The method according to claim 1, wherein conditions of the semi insulating SiC layer are chosen such that deep intrinsic defects dominate over shallow point defects which is achieved by one of:
during the growth a C/Si ratio is kept between 0.9-3, or
during the growth a C/Si ratio is kept between 0.9-1.5.

6. The method according to claim 1, where the substrate is one of:
an n+ SiC wafer, or
a silicon wafer.

7. The method according to claim 1, wherein the grown semi insulating SiC layer is made isotope enriched.

8. The method according to claim 1, further comprising:
growing a Group III-N HEMT structure on top of the SI SIC semi insulating SiC layer.

9. The method according to claim 8, further comprising:
growing the semi insulating SiC layer on a substrate, and
polishing off the substrate after growing the HEMT structure.

10. The method according to claim 8, wherein the semi insulating SiC layer is formed according to B), the method further comprising:
thinning down the semi insulating SiC layer to between 50 μm and 150 μm after growing the HEMT structure.

11. The method according to claim 8, wherein the Group III-N material is one of:
AlGaN/GaN, or
a combination of In, Ga, Al.

11. The method according to claim 1, wherein according to A) the grown semi insulating SiC layer has a thickness in a range of 50 μm-200 μm.

12. The method according to claim 1, wherein according to A) the grown semi insulating SiC layer has a thickness in a range of 50 μm-150 μm
